(19) United States
(12) Patent Application Publication
(10) Pub. No.: US 2025/0201771 A1
(43) Pub. Date: Jun. 19, 2025

(54) LAMINATED SUBSTRATE PACKAGES CONFIGURED FOR COUPLING TO ISOLATION TRANSFORMERS

(71) Applicant: Allegro MicroSystems, LLC, Manchester, NH (US)

(72) Inventors: Harry Chandra, Phoenix, AZ (US); Natasha Healey, Manchester, NH (US)

(73) Assignee: Allegro MicroSystems, LLC, Manchester, NH (US)

(21) Appl. No.: 18/538,520

(22) Filed: Dec. 13, 2023

(51) Int. Cl. H01L 25/065; H01F 27/28; H01L 23/31; H01L 23/36; H01L 23/498; H01L 23/538

(52) U.S. Cl. CPC H01L 25/0655; H01F 27/2804; H01L 23/3121; H01L 23/36; H01L 23/49811; H01L 23/5384; H01L 23/5386

(57) ABSTRACT

Systems, structures, packages, circuits, and methods provide IC packages with laminated substrates configured for use with or coupling to a transformer package or assembly. IC packages can include a substrate having an encapsulant presenting an encapsulating volume for encapsulation of one or more IC die. The encapsulating volume can be configured below, at, or above a main surface of the substrate, with the packages including receiving/mounting structures to accommodate coupling of a transformer assembly. The packages and modules may include various types of circuits; in some examples, chips, chip packages, or modules may include a gate driver or other high voltage circuit.

### BACKGROUND

Solid state switches typically include a transistor structure. The controlling electrode of the switch, usually referred to as its gate (or base), is typically controlled (driven) by a switch drive circuit, sometimes also referred to as gate drive circuit. Such solid state switches are typically voltage-controlled, turning on when the gate voltage exceeds a manufacturer-specific threshold voltage by a margin, and turning off when the gate voltage remains below the threshold voltage by a margin.

Switch drive circuits typically receive their control instructions from a controller such as a pulse-width-modulated (PWM) controller via one or more switch driver inputs. Switch drive circuits deliver their drive signals directly (or indirectly via networks of active and passive components) to the respective terminals of the switch (gate and source).

Some electronic systems, including ones with solid state switches, have employed galvanic isolation to prevent undesirable DC currents flowing from one side of an isolation barrier to the other. Such galvanic isolation can be used to separate circuits in order to protect users from coming into direct contact with hazardous voltages.

Various transmission techniques are available for signals to be sent across galvanic isolation barriers including optical, capacitive, and magnetic coupling techniques. Magnetic coupling typically relies on use of a transformer to magnetically couple circuits on the different sides of the transformer, typically referred to as the primary and secondary sides, while also providing galvanic separation of the circuits.

Transformers used for magnetic-coupling isolation barriers typically utilize a magnetic core to provide a magnetic path to channel flux created by the currents flowing in the primary and secondary sides of the transformer. Magnetic-coupling isolation barriers have been shown to have various drawbacks, including manufacturing problems, for integrated circuit (IC) packages due to the included magnetic core.

### SUMMARY

Aspects of the present disclosure are directed to IC packages having laminated substrates with receiving structures for compact mounting of isolation transformer packages providing galvanic isolation.

A general aspect of the present disclosure includes an integrated circuit (IC) package. The integrated circuit can include a substrate having opposed first and second surfaces and including first and second pluralities (groups) of conductive traces, where the first and second pluralities of conductive traces are galvanically separate, and where the first surface may include a plurality of receiving structures configured for connection to an isolation transformer assembly; first and second semiconductor die (a.k.a., IC die) disposed on the first surface of the substrate and connected to the first and second pluralities of conductive traces, respectively; and an encapsulant disposed on the first surface and configured as an encapsulating volume encapsulating the first and second semiconductor die, where the encapsulating volume has a height sufficient to allow the plurality of receiving structures to receive the isolation transformer assembly.

Implementations may include one or more of the following features. The first surface of the substrate of the IC package can include a recess, and the first and second semiconductor die may be disposed in the recess. The plurality of receiving structures may include structures (e.g., pedestals or posts) having a height, and where the encapsulating volume may have a height less than or equal to the height of the pedestals. The plurality of receiving structures may include solder pads. The encapsulant may include molding material. The encapsulant may include a silicone material. The isolation transformer assembly may include a molded package having a plurality of exposed conductive structures corresponding in number to the plurality of receiving structures. The first and second pluralities of conductive traces may include first and second pluralities of I/O structures such as solder pads. The first and second pluralities of solder pads may be disposed on the second surface of the substrate, respectively. The first and second pluralities of solder pads may include land grid array (LGA) pads. The first and second pluralities of I/O structures or solder pads may be disposed on first and second side surfaces (e.g., including wettable flanks) of the substrate, respectively. The first and second pluralities of I/O structures or solder pads may include plated through holes or vias. The first and second pluralities of I/O structures or solder pads may include plated blind holes or vias. The first and second pluralities of conductive traces may include first and second pluralities of solder pads disposed on the second surface of the substrate, respectively. The IC package may include one or more heat-sink (thermally conductive) structures disposed on the second surface of the substrate. The first and second semiconductor die may include first and second integrated circuits (ICs), respectively. The second IC may include a gate driver. The substrate may include a printed circuit board (PCB) and/or other laminated substrate structure. The IC package may include an isolation transformer package connected to the plurality of receiving structures, the isolation transformer package including a transformer having first and second transformer coils that are galvanically separated and connected to respective pairs of conductive leads. The transformer package further may include a magnetic core having a soft ferromagnetic material, where the first and second transformer coils are configured about the magnetic core.

Another general aspect of the present disclosure includes a method of making an integrated circuit (IC) package. The method can include providing a substrate having opposed first and second surfaces and including first and second pluralities (groups) of conductive traces, where the first and second pluralities of conductive traces are galvanically separate, and where the first surface may include a plurality of receiving structures configured for connection to an isolation transformer assembly; providing first and second semiconductor die disposed on the first surface of the substrate and connected to the first and second pluralities of conductive traces, respectively; and providing an encapsulant disposed on the first surface and configured as an encapsulating volume encapsulating the first and second semiconductor die, where the encapsulating volume has a height sufficient to allow the plurality of receiving structures to receive the isolation transformer assembly.

Implementations may include one or more of the following features. The substrate provided may include a recess on the first surface, and the first and second semiconductor die may be disposed in the recess. The plurality of receiving structures may include pedestals (posts or columns) having a height, and the encapsulating volume may have a height less than or equal to the height of the receiving structures (e.g., pedestals). The plurality of receiving structures may include solder pads. The encapsulant may include molding, potting, and/or dielectric material(s). The encapsulant may include a silicone material. The isolation transformer assembly may include a molded package having a plurality of exposed conductive structures corresponding in number to the plurality of receiving structures. The first and second pluralities of conductive traces may include first and second pluralities of I/O structures such as solder pads. The first and second pluralities of I/O structures or solder pads can be disposed on the second surface of the substrate, respectively. The first and second pluralities of I/O structures or solder pads may include land grid array (LGA) pads. The first and second pluralities of I/O structures or solder pads can be disposed on first and second side surfaces (e.g., including wettable flanks) of the substrate, respectively. The first and second pluralities of I/O structures or solder pads may include plated through holes or vias. The first and second pluralities of I/O structures or solder pads may include plated blind holes or vias. The first and second pluralities of conductive traces may include first and second pluralities of I/O structures or solder pads disposed on the second surface of the substrate, respectively. The method may include one or more heat-sink (thermally conductive) structures disposed on the second surface of the substrate. The first and second semiconductor die may include first and second integrated circuits (ICs), respectively. The second IC may include a gate driver. The substrate may include a printed circuit board (PCB) and/or other laminated substrate structure. The method may include providing an isolation transformer package connected to the plurality of receiving structures, the isolation transformer package including a transformer having first and second transformer coils that are galvanically separated. The transformer package further may include a magnetic core having a soft ferromagnetic material, where the first and second transformer coils are configured about the magnetic core and connected to respective pairs of conductive leads.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The manner and process of making and using the disclosed embodiments may be appreciated by reference to the figures of the accompanying drawings. In the figures like reference characters refer to like components, parts, elements, or steps/actions; however, similar components, parts, elements, and steps/actions may be referenced by different reference characters in different figures. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1 is a perspective view of an example integrated circuit (IC) laminated substrate package having a recessed substrate configured for use with an isolation transformer package, in accordance with the present disclosure;

FIG. 2 is a diagram including views (A)-(D) showing top, side, bottom, and perspective views of an example integrated circuit (IC) laminated substrate package having a recessed substrate configured for use with an isolation transformer package, in accordance with the present disclosure;

FIG. 3 shows top and bottom perspective views of an example integrated circuit (IC) laminated substrate package having a recessed substrate configured for use with an isolation transformer package, in accordance with the present disclosure;

FIGS. 4A-4C shows top perspective views (A)-(B) of alternate configurations of input/output (I/O) structures for integrated circuit (IC) laminated substrate packages, in accordance with the present disclosure;

FIG. 5 is a top perspective view of an example isolation transformer package, in accordance with the present disclosure;

FIGS. 6A-6B show perspective and side views of an example integrated circuit (IC) laminated substrate package having pedestals configured for use with an isolation transformer package, in accordance with the present disclosure;

FIGS. 7A-7C show respective different stages of fabrication of an example integrated circuit (IC) laminated substrate package having pedestals for coupling to an isolation transformer package, in accordance with the present disclosure;

FIGS. 8A-8B show views of alternate embodiments of an integrated circuit (IC) laminated substrate package with pedestals configured for use with a piggyback transformer package, in accordance with the present disclosure; and

FIG. 9 shows steps for an example method of fabricating an integrated circuit (IC) laminated substrate package configured for use with an isolation transformer package, in accordance with the present disclosure.

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, structures, circuits, and methods providing semiconductor or IC die packages with laminated substrates that can be used with galvanic isolation transformers and transformer structures that can be used for galvanic isolation (a.k.a., voltage isolation). In some embodiments, an isolation transformer may have, e.g., a step up, a step down, or a power transformer configuration. In some embodiments and examples can include integrated circuit (IC) die, e.g., packaged or unpackaged.

The IC (IC die) packages and modules may include various types of circuits. In some examples, one or more (e.g., first and second) semiconductor die having one or more integrated circuits (a.k.a., “IC die”) can be included in the packages. In some embodiments and examples, IC die may be packaged or unpackaged. Such integrated circuits can include, e.g., but are not limited to, high-voltage circuits such as gate drivers configured to drive an external gate on a solid-state switch, e.g., a field effect transistor (FET), a metal oxide semiconductor FET (MOSFET), a metal semiconductor FET (MESFET), a gallium nitride FET (GaN FET), a high electron mobility transistor (HEMT), a silicon carbide FET (SIC FET), an insulated gate bipolar transistor (IGBT), or another load.

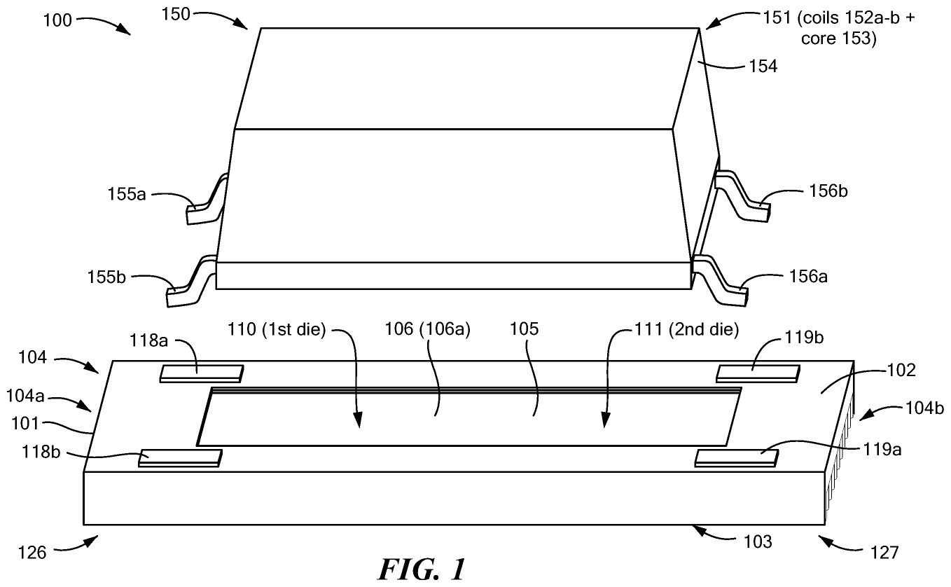

FIG. 1 is a perspective view of an example integrated circuit (IC) laminated substrate package 100 having a recessed substrate configured for use with an isolation transformer package 150, in accordance with the present disclosure.

Package 100 includes a substrate 101 with opposed first and second surfaces (sides) 102, 103. Substrate 101 can include a laminated structure in some embodiments. Substrate 101 can include a plurality of conductive structures or traces 104, which may be on one or more surfaces of substrate 101 and/or included in the interior of substrate 101. Any suitable conductive material(s) can be used for conductive structures/traces 104. In some embodiments, copper may be used for structures/traces 104. The plurality of conductive traces 104 can include a first plurality or group 104a and a second plurality or group 104b that are galvanically separate from one another. The first group 104a can include a plurality of exposed portions that are exposed at a first area (or areas) of the substrate 101 and the second group 104b can include a plurality of exposed portions that are exposed at a second area (or areas) of the substrate 101 for input/output (I/O) connections to other devices, circuits, or components, e.g., shown as respective groups of solder contacts (pads) 126 and 127.

Substrate 101 is shown including a cavity or recess 105 on first surface (side) 102. First and second (semiconductor) IC die 110, 111 can be disposed in recess 105. First and second IC die 110, 111 can be connected to substrate 101 with suitable connections, e.g., adhesive (not shown) and wirebonds (not shown). An encapsulant 106 can be provided (e.g., dispensed, poured, introduced to) and disposed in recess 105 on the first surface 102 and configured as an encapsulating (encapsulation) volume 106a encapsulating the first and second IC 110, 111 die. A plurality of receiving structures are present and may include first and second galvanically separated groups, shown as 118a-b and 119a-b. The plurality of receiving structures are connected to IC die 110, 111 (by conductive traces 104a-b) and are configured to receive or be connected to an isolation transformer assembly, as indicated by isolation transformer package 150. The encapsulating volume 106a has a height sufficient to allow the plurality of receiving structures 118a-b, 119a-b to receive the isolation transformer assembly 150. Isolation transformer assembly/package 150 includes a transformer 151 having first and second (primary and secondary) transformer coils 152a-b and may include a magnetic core 153. Transformer 151 is disposed within package body 154 and has external I/O connections in the form of leads 155a-b and 156a-b.

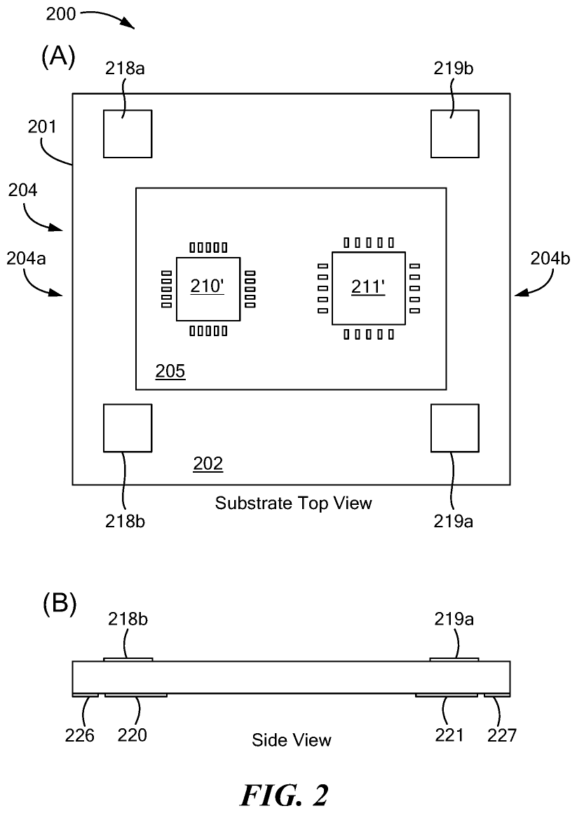

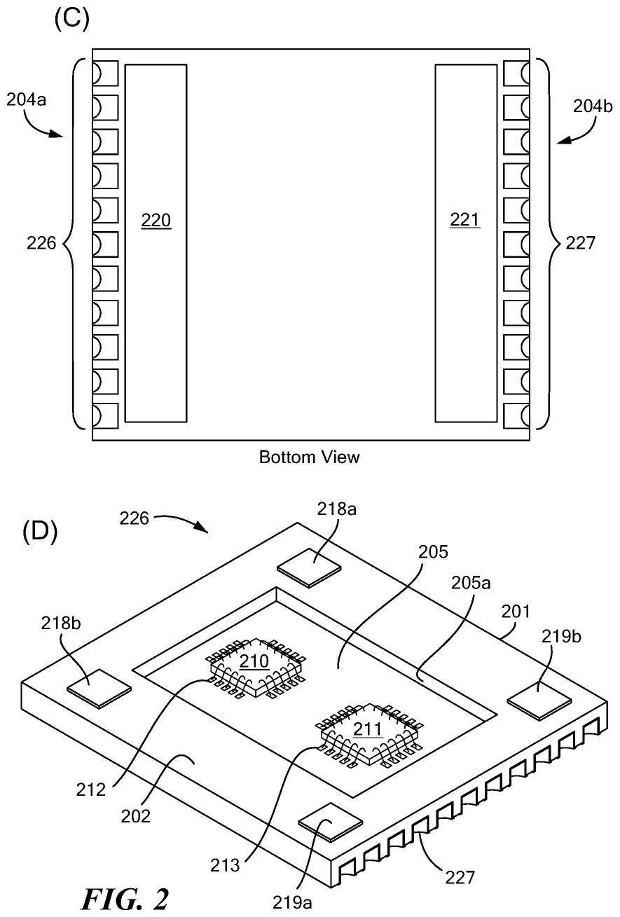

FIG. 2 is a diagram including views A-C showing top, bottom, and perspective views of an example integrated circuit (IC) laminated substrate package 200 having a recessed substrate configured for use with an isolation (piggyback) transformer package, in accordance with the present disclosure.

As shown in view (A), package (package structure) 200 includes substrate 201 with first and second opposed sides (surfaces) 202, 203. Substrate 201 can include a laminated structure in some embodiments. Substrate 201 can include a plurality of conductive structures or traces 204, which may be on one or more surfaces of substrate 201 and/or included in the interior of substrate 201. The plurality of conductive traces 204 can include a first group 204a and a second group 204b that are galvanically separate from one another. The first group 204a can include a plurality of exposed portions that are exposed at a first area (or areas) of the substrate 201 and the second group 204b can include a plurality of exposed portions that are exposed at a second area (or areas) of the substrate 201 for input/output (I/O) connections to other devices, circuits, or components, e.g., shown respectively as groups of solder contacts (pads) 226 and 227.

Substrate 201 is shown including a recess or cavity 205 on first surface (side) 202, as shown. First and second (semiconductor) IC die 210, 211 can be disposed on respective die pads 210′, 211′ in recess 205. First and second IC die 210, 211 can be connected to substrate 201 with suitable connections, e.g., adhesive (not shown) and wirebonds 213, 213 shown in view (D). An encapsulant (e.g., similar to encapsulant 106 in FIG. 1) can be provided (e.g., dispensed, poured, introduced to) and disposed in recess 205 on the first surface 202 and configured as an encapsulating volume 206a encapsulating the first and second IC 210, 211 die. Any suitable material or materials may be used for encapsulant 206, e.g., one or more molding materials, potting materials, or dielectric materials.

A plurality of receiving structures are present for coupling structure 200 to an isolation transformer assembly (e.g., transformer package 150 of FIG. 1) configured to provide galvanic isolation of IC die 210, 211. The plurality of receiving structures can include first and second galvanically separated groups, shown as 218a-b and 219a-b. The plurality of receiving structures 218a-b and 219a-b are connected to IC die 211, 212 and are configured to receive or be connected to the isolation (piggyback) transformer assembly. The encapsulating volume presented by the encapsulant has a height sufficient to allow the plurality of receiving structures 218a-b, 219a-b to receive the isolation transformer assembly.

View (B) shows a side view of substrate 201 with receiving 218a-b and 219a-b disposed on surface 202. Thermally conductive thermal pads 220, 221 may be present in some embodiments to facilitate removal of heat generated during operation of components of package 200. First and second groups of solder contacts (pads) 226 and 227 are also shown.

View (C) is a bottom view of substrate 201 with thermal pads 220, 221 and solder contacts (pads) 226 and 227 disposed on or accessible from surface 203. Galvanically separate groups of conductive traces/structures 204a-b are also shown. In some embodiments, solder contacts 226 and 227 may be distributed along a wettable flank, as shown. Any suitable configurations may be used for solder contacts 227, 227 along a wettable flank.

View (D) shows a top perspective (isometric) view of package 200. Encapsulant is omitted from the drawing but, for an encapsulant step/process, would be disposed in cavity 205 on surface 202 for encapsulation of die 210, 211. The encapsulation volume formed by the encapsulant (around die 210, 211) would have a height sufficient (sufficiently low) to allow a transformer assembly to be mounted/connected to receiving structures 218a-b and 219a-b. For example, in some embodiments, an encapsulant disposed in cavity 205 and configured as an encapsulation volume may have a height equivalent to (or substantially equivalent to) the height of cavity 205 as indicated by cavity sidewall 205a in view (D). A transformer package (e.g., similar to package 150 in FIG. 1) mounted on package 200 can provide/facilitate power/control signal transfer between die 210, 211 while also providing/facilitating galvanic separation of the die 210, 211.

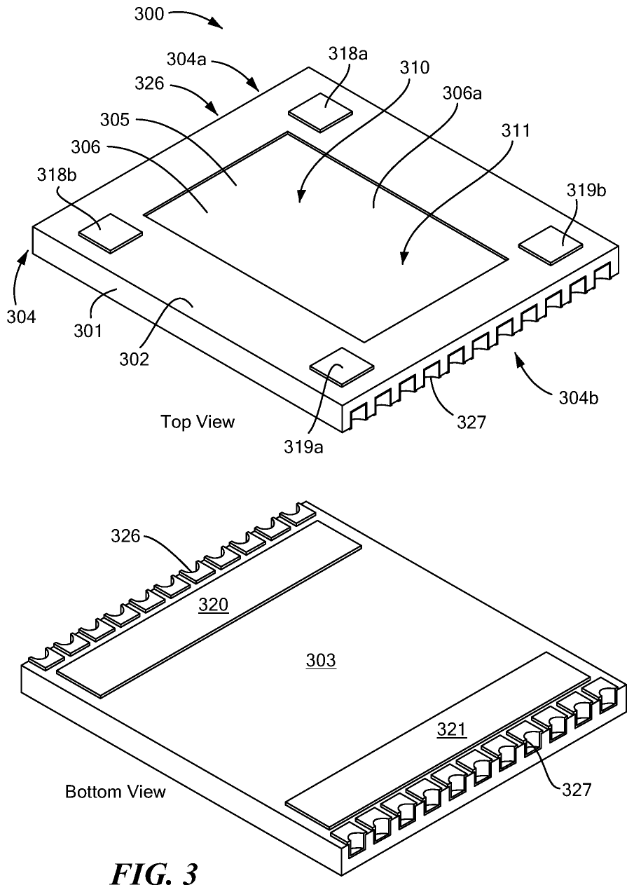

FIG. 3 showing top and bottom perspective views of an example integrated circuit (IC) laminated substrate package 300 having a recessed substrate configured for use with an isolation transformer package, in accordance with the present disclosure.

As shown in view (A), package (package structure) 300 includes substrate 301 with first and second opposed sides (surfaces) 302, 303. Substrate 301 can include a laminated structure in some embodiments. Substrate 301 can include a plurality of conductive structures or traces 304, which may be on one or more surfaces of substrate 301 and/or included in the interior of substrate 301. The plurality of conductive traces 304 can include a first group (plurality) 304a and a second group (plurality) 304b that are galvanically separate from one another. The first group 304a can include a plurality of exposed portions that are exposed at a first area (or areas) of the substrate 301 and the second group 304b can include a plurality of exposed portions that are exposed at a second area (or areas) of the substrate 301 for input/output (I/O) connections to other devices, circuits, or components, e.g., groups of solder contacts (pads) 326 and 327, respectively. In some embodiments, solder contacts 326 and 327 may be distributed along a wettable flank, as shown. Any suitable configurations may be used for solder contacts 327, 327 along a wettable flank.

Substrate 301 can include a cavity/recess (depression or recessed surface) 305 on first surface (side) 302, as shown. First and second (semiconductor) IC die 310, 311 can be disposed in recess 305. First and second IC die 310, 311 can be connected to substrate 301 with suitable connections, e.g., adhesive (not shown) and wirebonds (not shown). An encapsulant (e.g., similar to encapsulant 106 in FIG. 1) can be provided (e.g., dispensed, poured, introduced to) and disposed in recess 305 on the first surface 302 and configured as an encapsulating volume 306a encapsulating the first and second IC 310, 311 die. A plurality of receiving structures are present and may include first and second galvanically separated groups, shown as 318a-b and 319a-b. The plurality of receiving structures 318a-b and 319a-b are connected to IC die 310, 311 (by conductive structures/traces 304a-b) and are configured to receive or be connected to an isolation transformer assembly (e.g., transformer package 150 of FIG. 1). The encapsulating volume 306a has a height sufficient to allow the plurality of receiving structures 318a-b, 319a-b to receive the isolation transformer assembly, e.g., with the isolation transformer assembly mounted to substrate 301.

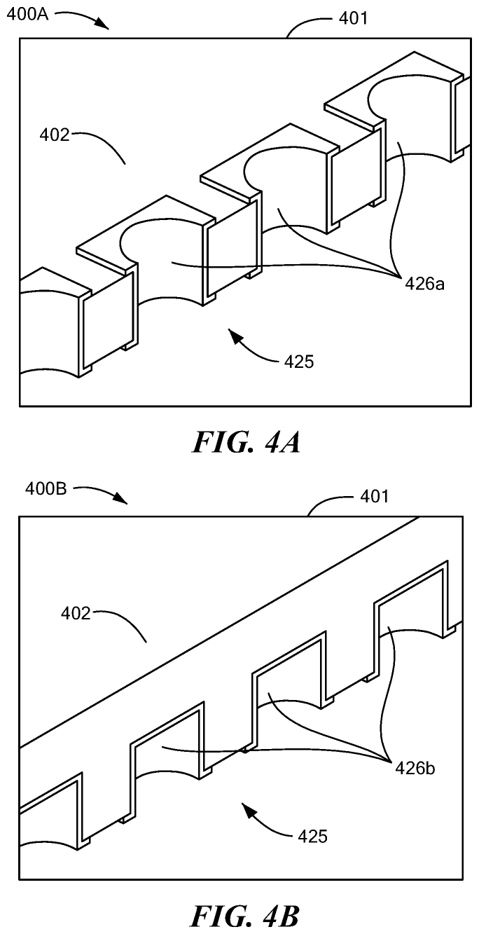

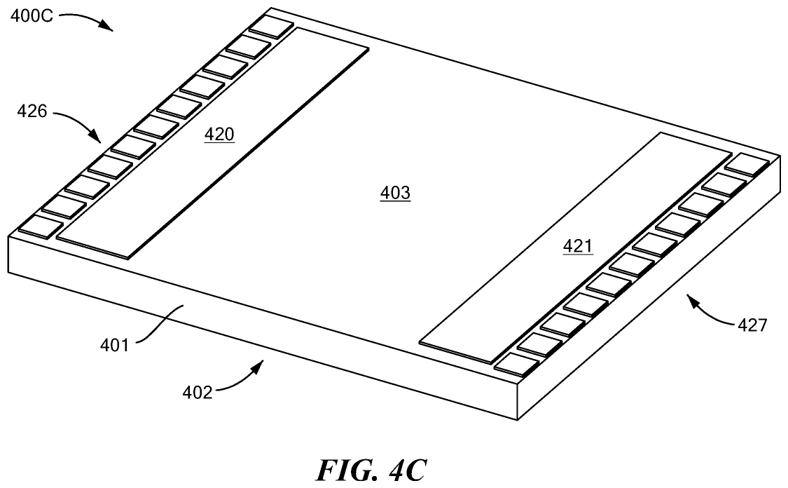

FIGS. 4A-4C show views (A)-(C) of alternate configurations 400A-400C of input/output (I/O) structures for example integrated circuit (IC) laminated substrate packages, in accordance with the present disclosure.

View (A) shows configuration 400A with substrate 401 having top surface 402 and a wettable flank 425 with I/O connections (structures) configured as plated through holes 426a.

View (B) shows configuration 400B with substrate 401 having top surface 402 and a wettable flank 425 with I/O connections (structures) configured as plated partial through holes 426b.

View (C) shows configuration 400C with substrate 401 having top and bottom surfaces 402, 403 and I/O connections configured as groups of solder pads 426, 427. In some embodiments, solder pad groups 426, 427 can be connected, respectively, to galvanically separated groups of conductive structures/traces (e.g., groups 204a-204b shown for FIG. 2).

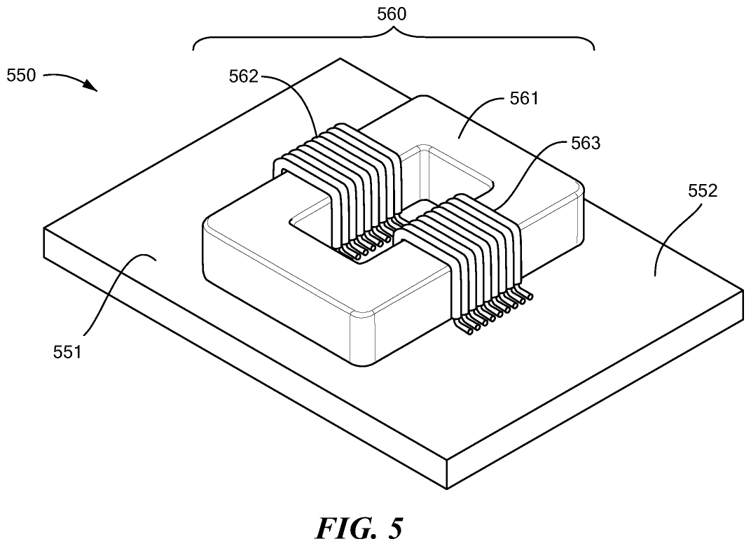

FIG. 5 is a top perspective view of an example isolation transformer package 550, in accordance with the present disclosure. Package 550 includes a substrate 551 having first and second sides 551, 552. Any suitable substrate material(s) may be used for substrate 551. Package 550 also includes a transformer 560 having first and second transformer coils 561, 562. The coils may be configured (e.g., wound) about a magnetic core 563. In some embodiments, magnetic core may include a soft (magnetic property) ferromagnetic material. Coils 561 and 562 can be galvanically separate and form primary and secondary sides of transformer 560. Package 550 can include material (e.g., encapsulant and/or molding material) forming/completing a package body (not shown) and I/O leads (e.g., similar to leads 155a-b and 156a-b shown in FIG. 1) connected to first and second coils 561, 562. Of course, transformer package 550 is shown by way of example and other configurations of transformer packages/assemblies (a.k.a., piggyback transformers) may be used in or for embodiments of the present disclosure.

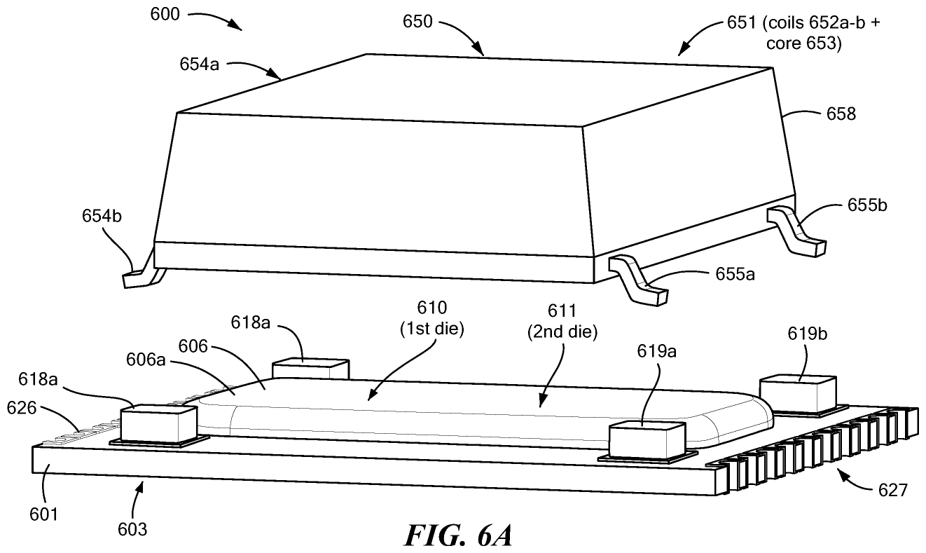

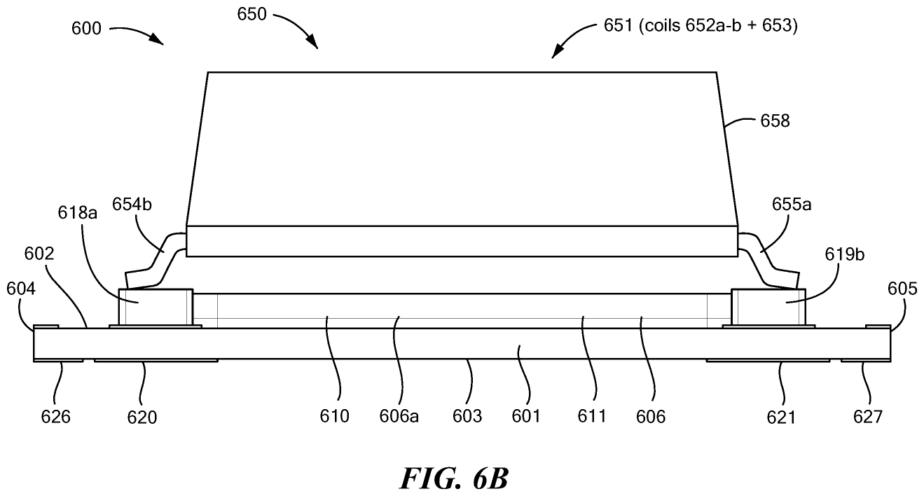

FIGS. 6A-6B show perspective and side views of an example integrated circuit (IC) laminated substrate package 600 having pedestals configured for use with an isolation transformer package, in accordance with the present disclosure.

As shown in FIG. 6A, package (package structure) 600 includes a substrate 601 with opposed first and second surfaces (sides) 602, 603. Substrate 601 can include a laminated structure, e.g., a printed circuit board (PCB), in some embodiments. Substrate 601 can include a plurality of conductive structures or traces 604, which may be on one or more surfaces of substrate 601 and/or included in the interior of substrate 601. The plurality of conductive traces 604 can include a first group 604a and a second group 604b that are galvanically separate from one another. The first group 604a can include a plurality of exposed portions that are exposed at a first area (or areas) of the substrate 601 and the second group 604b can include a plurality of exposed portions that are exposed at a second area (or areas) of the substrate 601 for input/output (I/O) connections to other devices, circuits, or components, e.g., groups of solder contacts (pads) 626 and 627, respectively.

Substrate 601 can include an encapsulant 606 configured as an encapsulation/encapsulating volume 606a on first surface (side) 602, as shown. First and second (semiconductor) IC die 610, 611 can be disposed in and encapsulated by encapsulant 606. First and second IC die 611, 612 can be connected to substrate 601 with suitable connections, e.g., adhesive (not shown) and wirebonds (not shown). An encapsulant 606 can be provided (e.g., dispensed, poured, introduced to) and disposed on the first surface 602 and configured as an encapsulating volume 606a encapsulating the first and second IC 611, 612 die. A plurality of receiving structures are present and may include first and second galvanically separated groups, shown as 618a-b and 619a-b. The plurality of receiving structures 618a-b and 619a-b are connected to IC die 611, 612 and are configured to receive or be connected to an isolation transformer assembly, as indicated by isolation transformer package 650. Isolation transformer assembly/package 650 includes a transformer 651 having first and second (primary and secondary) transformer coils 652a-b and a magnetic core 653. Transformer 651 is disposed within package body 654 and has external I/O connections in the form of leads 655a-b and 656a-b.

The plurality of receiving structures 618a-b and 619a-b has a height sufficient accommodate the encapsulating volume 606a and is configured to receive the isolation transformer assembly 650. Any suitable material(s) and/or structures may be used for receiving structures 618a-b and 619a-b. In some embodiments, receiving structures 618a-b and 619a-b can include conductive material(s), e.g., copper pillars/posts. In some embodiments, receiving structures 618a-b and 619a-b can include core material(s) surrounded by different material(s). In some embodiments, 18a-b and 619a-b can include laminated structures, e.g., PCB structures. In some embodiments, receiving structures 618a-b and 619a-b can include non-conductive material(s).

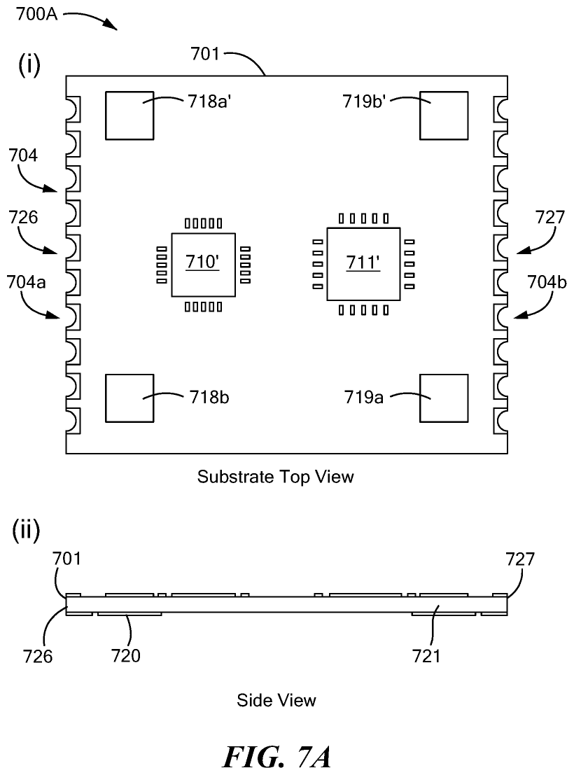

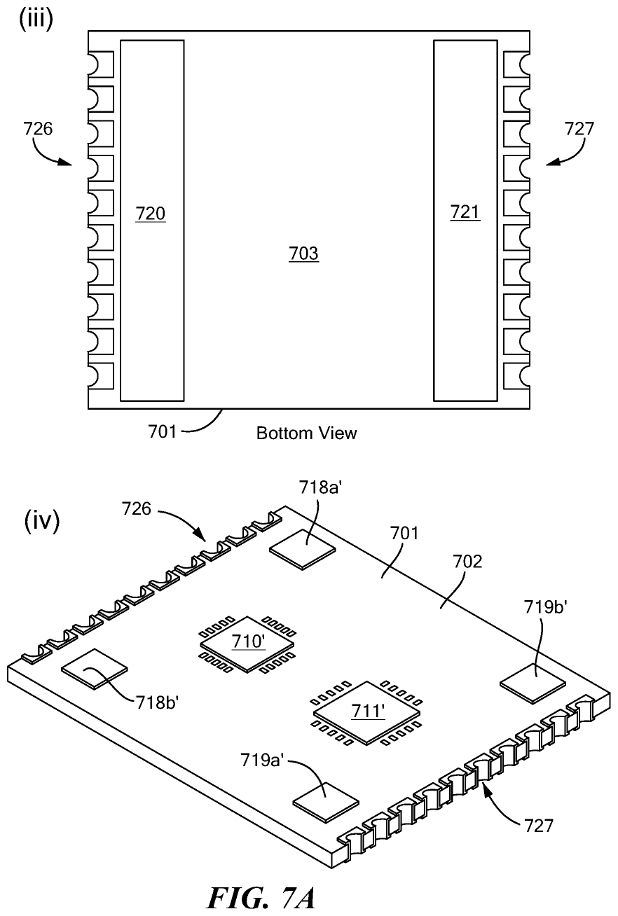

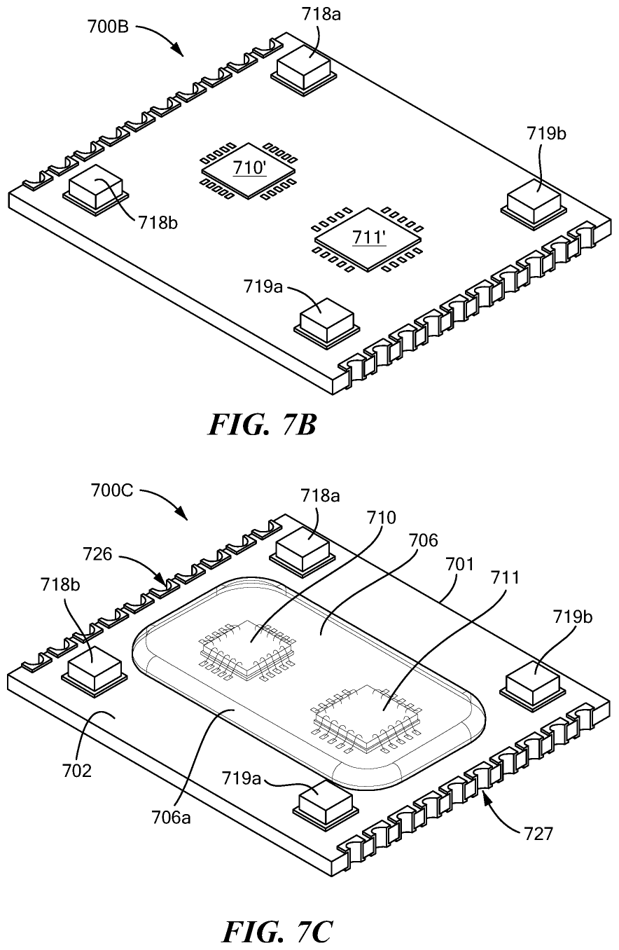

FIGS. 7A-7C shows respective views of different stages of fabrication of an example integrated circuit (IC) laminated substrate package having pedestals for coupling to an isolation transformer package, in accordance with the present disclosure.

FIG. 7A includes views (i)-(iv) showing top, side, bottom, and perspective views of example integrated circuit (IC) substrate structure 700A configured for pedestals used for receiving a piggyback transformer package, in accordance with the present disclosure.

As shown in FIG. 7A, structure 700A includes substrate 701 with first and second opposed sides (surfaces) 702, 703. Substrate 701 can include a laminated structure—e.g., PCB, ceramic, or alternating layers of glass and metal, etc. —in some embodiments. Substrate 701 can include a plurality of conductive structures or traces 704, which may be on one or more surfaces of substrate 701 and/or included in the interior of substrate 701. Any suitable conductive material(s) can be used for conductive structures/traces 704. The plurality of conductive traces 704 can include a first group 704a and a second group 704b that are galvanically separate from one another. The first group 704a can include a plurality of exposed portions that are exposed at a first area (or areas) of the substrate 701 and the second group 704b can include a plurality of exposed portions that are exposed at a second area (or areas) of the substrate 701 for input/output (I/O) connections to other devices, circuits, or components, e.g., shown respectively as groups of solder contacts (pads) 726 and 727.

First and second (semiconductor) IC die 710, 711 (FIG. 7C) can be disposed on respective die pads 710′, 711′ on surface 702. First and second IC die 710, 711 can be connected to substrate 701 with suitable connections, e.g., adhesive (not shown) and wirebonds 713, 713 shown in view (iv). Package 700 can include an encapsulant (shown in FIG. 7C) that is configured as an encapsulating volume encapsulating the first and second IC 710, 711 die.

As shown in view (i), a plurality of receiving structures are present for coupling structure 700A to an isolation transformer assembly configured to provide galvanic isolation of IC die 710, 711 (shown in FIG. 7C) disposed on die pads 710′, 711′. The plurality of receiving structures can include first and second galvanically separated groups, shown as pads 718a-b′ and 719a-b′ which can be joined with or connected to additional receiving structures (e.g., pedestals 718a-b, 719a-b, shown in FIGS. 7B-7C) that are configured to receive an isolation transformer (or other) package/assembly at a desired/designed distance from surface 702 of substrate 701. The plurality of receiving structures, e.g., represented by pads 718a-b′ and 719a-b′, can be connected to IC die 710, 711 (shown in FIG. 7C) disposed on die pads 710′, 711′ by groups of conductive structures/traces 704a-b, respectively.

FIG. 7A, view (ii), shows a side view of substrate 701. As shown, optional thermally conductive thermal pads 720, 721 may be present in some embodiments to facilitate removal of heat generated during operation of components of package structure 700. First and second groups of solder contacts (pads) 726 and 727 are also shown.

FIG. 7A, view (iii), shows a bottom view of substrate 701. Thermally conductive thermal pads 720, 721 are shown disposed on surface 703. Groups of solder contacts (pads) 726 and 727 may be disposed on or accessible from surface 703. In some embodiments, solder contacts 726 and 727 may be distributed along a side of substrate 701 as a wettable flank, as shown. Any suitable configurations may be used for solder contacts 727, 727 along a wettable flank, e.g., plated partial through holes, plated through holes, etc.

FIG. 7A, view (iv), shows a top perspective (isometric) view of structure 700A. As described in further detail below, semiconductor (IC) die may be disposed on die pads 710′, 711′ and encapsulated with an encapsulant material or materials.

FIG. 7B shows integrated circuit (IC) substrate structure 700B with additional receiving structures, e.g., pedestals 718a-b and 719a-b, added to structure 700A. Pedestals 718a-b, 719a-b can receive/support a transformer assembly/package (e.g., similar to package 150 shown for FIG. 1 or package 550 shown for FIG. 5). Any suitable material (a) may be used for pedestals 718a-b and 719a-b. Pedestals 718a-b and 719a-b may be connected to conductive traces/structures 704a-b, respectively, and may be galvanically separated.

FIG. 7C shows integrated circuit (IC) substrate structure 700C including IC die 710 and 711 encapsulated by encapsulant 706. Encapsulant 706 is shown as being transparent so that ID die 710 and 711 can be seen. Relative to structure 700B, structure 700C adds encapsulant 706 and IC die 710, 711. IC die 710 and 711 are shown mounted on associated die pads 710′ and 711′. Encapsulant 706 is shown disposed on the first surface 702 of substrate 701 and configured as an encapsulating volume 706a encapsulating the first and second IC 710, 711 die. In some embodiments, the height of encapsulating volume 706a is less than or equal to the height of pedestals (receiving structures) 718a-b and 719a-b, so that a transformer package (e.g., transformer package 150 of FIG. 1) may be received by pedestals 718a-b and 719a-b. As lead structures/configurations of a transformer package may provide some physical clearance (offset distance), the height of the encapsulation volume may exceed that of the pedestals 718a-b and 719a-b in some embodiments while still allowing connection of the transformer package to the pedestals 718a-b and 719a-b.

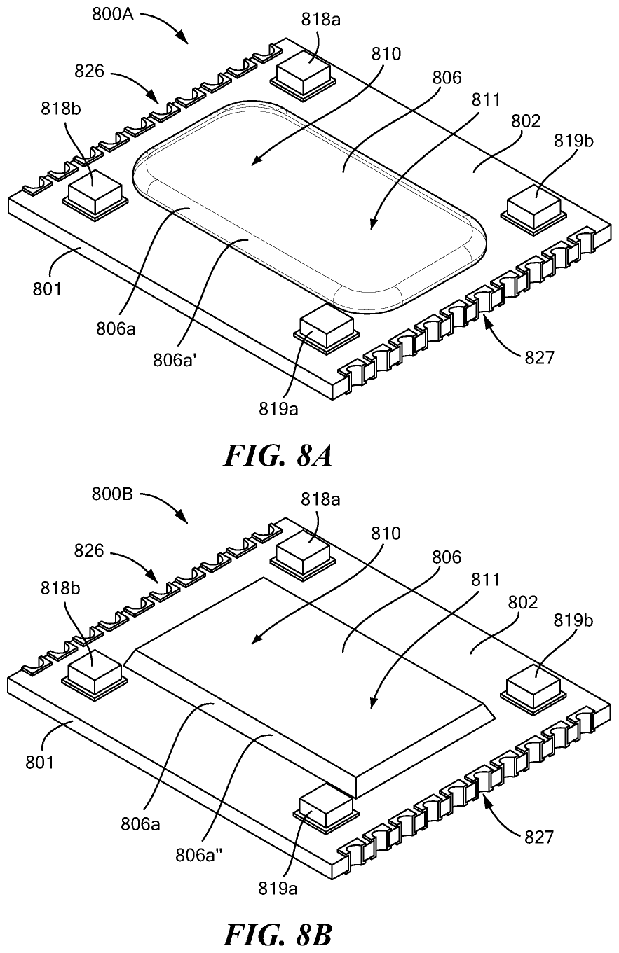

FIGS. 8A-8B shows top perspective views of alternate embodiments 800A-800B of an integrated circuit (IC) laminated substrate package having pedestals configured for use with an isolation transformer package, in accordance with the present disclosure.

FIG. 8A shows package structure 800A including substrate 801 with first and second opposed sides 802, 803. Substrate 801 may include a laminated structure, e.g., PCB, in some embodiments. Substrate 801 can include a plurality of conductive structures or traces 804, which may be on one or more surfaces of substrate 801 and/or included in the interior of substrate 801. The plurality of conductive traces 804 can include a first group 804a and a second group 804b that are galvanically separate from one another. The first group 804a can include a plurality of exposed portions that are exposed at a first area (or areas) of the substrate 801 and the second group 804b can include a plurality of exposed portions that are exposed at a second area (or areas) of the substrate 801 for input/output (I/O) connections to other devices, circuits, or components, e.g., shown respectively as groups of solder contacts (pads) 826 and 827. Encapsulant 806 is shown disposed on surface 802 and forming an encapsulating volume surrounding first and second IC (semiconductor) die 810, 811. First and second (semiconductor) IC die 810, 811 can be disposed on respective die pads (not shown) on surface 802. First and second IC die 810, 811 can be connected to substrate 801 with suitable connections, e.g., adhesive and/or wirebonds. Encapsulating volume 806a is shown as having an oval shape 806a′.

Package structure 800A includes a plurality of receiving structures, e.g., posts or pedestals (818+819), which can include first and second galvanically separated groups, shown as pairs of pedestals (pedestal pairs) 818a-b and 819a-b. The plurality of receiving structures (pedestals) 818a-b and 819a-b are connected to IC die 810, 811 (e.g., via conductive structure groups 804a and 804b) and are configured to receive and/or be connected to an isolation transformer assembly (e.g., transformer package 150 of FIG. 1).

FIG. 8B shows structure 800B, which is similar to structure 800A except that encapsulating volume 806a is shown having a generally rectangular shape 806a″. Of course, an encapsulation volume 806a may have other shapes in other embodiments of the present disclosure. In some embodiments, an encapsulation volume may have multiple surfaces (e.g., stepped surfaces) and/or a compound shape (e.g., an oval region merged with a rectangular region).

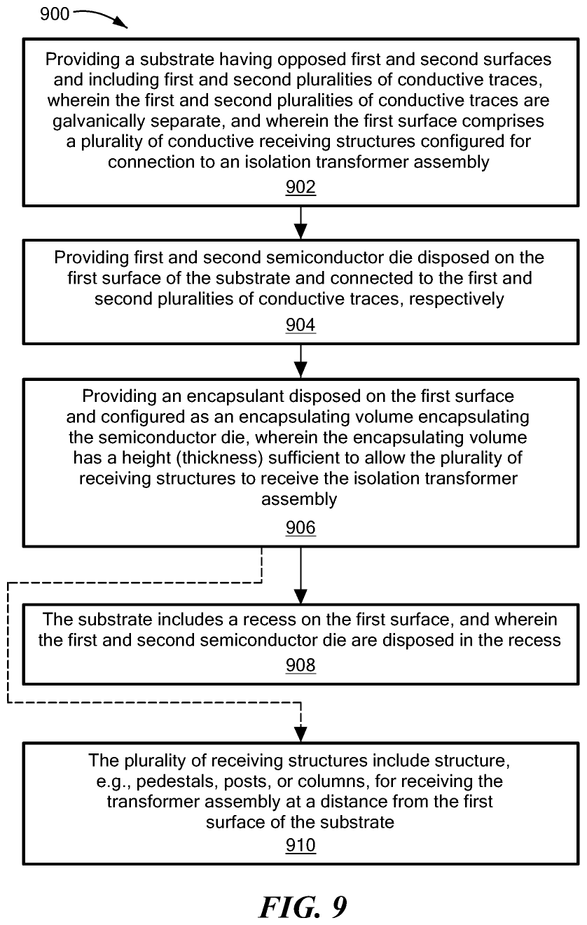

FIG. 9 shows steps for an example method of fabricating an integrated circuit (IC) laminated substrate package configured for use with an isolation transformer package, in accordance with the present disclosure.

Method 900 can include providing a substrate having opposed first and second surfaces and including first and second pluralities (groups) of conductive traces, wherein the first and second pluralities of conductive traces are galvanically separate, and wherein the first surface comprises a plurality of conductive receiving structures configured for connection to an isolation transformer assembly, as described at 902. In some embodiments, a substrate can include a laminated substrate or substrate structure, e.g., a PCB, a ceramic substrate, a glass substrate having one or more glass layers adjacent to metal layers, etc. One or more (e.g., first and second) semiconductor (IC) die can be disposed on (e.g., mounted on or connected to) the first surface of the substrate and connected to the first and second pluralities of conductive traces, respectively, as described at 904.

An encapsulant can be provided (e.g., dispensed, poured, introduced to) and disposed on the first surface of the substrate and configured as an encapsulating volume encapsulating the (e.g., first and second) semiconductor (IC) die, where the encapsulating volume has a height or thickness sufficient to allow the plurality of receiving structures to receive the isolation transformer assembly, as described at 906. In some embodiments, the substrate can include a recess on the first surface, and the (e.g., first and second) semiconductor (IC) die can be disposed in the recess, as described at 908. In some embodiments, the plurality of receiving structures can include receiving structures, e.g., pedestals, posts, or columns, having a height that allows the transformer package/assembly to be received at a distance from the first surface of the substrate while also accommodating the height of the encapsulating volume of encapsulant, as described at 910. In some embodiments, the encapsulating volume can have a height less than or approximately (substantially) equal to the height of the pedestals.

In some examples and/or embodiments, integrated circuits (ICs), e.g., IC die 210 and 211 in FIG. 2, or other conductive features of an IC package and/or the primary and secondary sides of a transformer of a transformer package (e.g., a piggyback transformer assembly or package), according to the present disclosure can be fabricated or configured to have a desired separation distance (d) between certain parts or features, e.g., to meet internal creepage or external clearance requirements for a given pollution degree rating as defined by certain safety standards bodies such as the Underwriters Laboratories (UL) and the International Electrotechnical Commission (IEC). For example, a separation distance may be between closest (voltage) points of the respective circuits, e.g., the low-voltage (primary) side and high-voltage (secondary) side. For further example, such a separation distance may be the distance between any two voltage points between the primary and secondary sides or a distance between exposed leads connected to the die connected to primary and secondary sides of a transformer, may be, may be approximately, or may be at least 1.2 mm, 1.4 mm, 1.5 mm, 3.0 mm, 4.0 mm, 5.5 mm, 7.2 mm, 8.0 mm, 10 mm, or 10+mm in respective examples. Such a distance between conductive portions or areas of die can include any insulation covering a conductor, e.g., such as plastic coating of a wire/lead. Other distances between conductive parts, components, and/or features of an IC/transformer package may also be designed and implemented, e.g., to meet desired internal creepage, voltage breakdown, or external clearance requirements, e.g., between external leads.

In some examples and embodiments, a dielectric material (e.g., gel, composite, solid, etc.) may be used for potting and/or protecting substrate (e.g., PCB) systems, assemblies, and/or packages, to protect die and/or interconnects from environment conditions and/or to provide dielectric insulation. In some examples, a dielectric material may include, but is not limited to, one or more of the following materials: DOWSIL™ EG-3810 Dielectric Gel (made available by The Dow Chemical Corporation, a.k.a., “Dow”) and DOWSIL™ EG-3896 Dielectric Gel (made available by Dow), which has the ability to provide isolation greater than 20 kV/mm. Other suitable gel or non-gel materials may also or instead be used, e.g., to meet or facilitate meeting/achieving voltage isolation specifications required by a given package design. DOWSIL™ EG-3810 is designed for temperature ranges from −60° C. to 200° C. and DOWSIL™ EG-3896 Dielectric Gel −40° C. to +185° C.; both of which can be used to meet typical temperature ranges for automotive applications.

Accordingly, embodiments and/or examples of the inventive subject matter can afford various benefits relative to prior art techniques. For example, embodiments and examples of the present disclosure can enable or facilitate use of smaller size packages for a given power, current. or voltage rating. Embodiments and examples of the present disclosure can enable or facilitate lower costs and higher scalability for manufacturing of IC packages/modules having voltage-isolated (galvanic isolation) IC die and transformers.

Various embodiments of the concepts, systems, devices, structures, and techniques sought to be protected are described above with reference to the related drawings. Alternative embodiments can be devised without departing from the scope of the concepts, systems, devices, structures, and techniques described.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration.” Any embodiment or design described as “exemplary” is not necessarily to be construed as preferred or advantageous over other embodiments or designs. The terms “one or more” and “at least one” indicate any integer number greater than or equal to one, i.e., one, two, three, four, etc.; those terms, however, may refer to fractional numbers/values where context admits. For example, a number of windings of a coil may have a fractional value of 1.5, 1.66, 2, 2.5, 3.3, etc. The term “plurality” indicates any integer or, where context admits (e.g., number of windings in a coil), fractional number greater than one. The term “connection” can include an indirect connection and a direct connection.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases do not necessarily refer to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, “top,” “bottom,” and derivatives of those terms relate to the described structures and methods as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. An integrated circuit (IC) package comprising:
a substrate having opposed first and second surfaces and including first and second pluralities of conductive traces, wherein the first and second pluralities of conductive traces are galvanically separate, wherein the first surface comprises a plurality of receiving structures configured for connection to an isolation transformer assembly;
first and second semiconductor die disposed on the first surface of the substrate and connected to the first and second pluralities of conductive traces, respectively; and
an encapsulant disposed on the first surface and configured as an encapsulating volume encapsulating the first and second semiconductor die, wherein the encapsulating volume has a height sufficient to allow the plurality of receiving structures to receive the isolation transformer assembly.

2. The IC package of claim 1, wherein the first surface of the substrate includes a recess, and wherein the first and second semiconductor die are disposed in the recess.

3. The IC package of claim 1, wherein the plurality of receiving structures comprise pedestals having a height, and wherein the encapsulating volume has a height less than or equal to the height of the pedestals.

4. The IC package of claim 1, wherein the plurality of receiving structures comprise solder pads.

5. The IC package of claim 1, wherein the encapsulant comprises molding material.

6. The IC package of claim 1, wherein the encapsulant comprises a silicone material.

7. The IC package of claim 1, wherein the isolation transformer assembly comprises a molded package having a plurality of exposed conductive structures corresponding in number to the plurality of receiving structures.

8. The IC package of claim 1, wherein the first and second pluralities of conductive traces comprise first and second pluralities of solder pads.

9. The IC package of claim 8, wherein the first and second pluralities of solder pads are disposed on the second surface of the substrate, respectively.

10. The IC package of claim 9, wherein the first and second pluralities of solder pads comprise land grid array (LGA) pads.

11. The IC package of claim 8, wherein the first and second pluralities of solder pads are disposed on first and second side surfaces of the substrate, respectively.

12. The IC package of claim 11, wherein the first and second pluralities of solder pads comprise plated through vias.

13. The IC package of claim 11, wherein the first and second pluralities of solder pads comprise plated blind vias.

14. The IC package of claim 1, wherein the first and second pluralities of conductive traces comprise first and second pluralities of solder pads disposed on the second surface of the substrate, respectively.

15. The IC package of claim 1, further comprising one or more heat-sink structures disposed on the second surface of the substrate.

16. The IC package of claim 1, wherein the first and second semiconductor die comprise first and second integrated circuits (ICs), respectively.

17. The IC package of claim 16, wherein the second IC comprises a gate driver.

18. The IC package of claim 1, wherein the substrate comprises a printed circuit board (PCB).

19. The IC package of claim 1, further comprising an isolation transformer package connected to the plurality of receiving structures, the isolation transformer package including a transformer having first and second transformer coils that are galvanically separated and connected to respective pairs of conductive leads.

20. The IC package of claim 19, wherein the transformer package further comprises a magnetic core having a soft ferromagnetic material, wherein the first and second transformer coils are configured about the magnetic core.

21. A method of making an integrated circuit (IC) package, the method comprising:
providing a substrate having opposed first and second surfaces and including first and second pluralities of conductive traces, wherein the first and second pluralities of conductive traces are galvanically separate, and wherein the first surface comprises a plurality of receiving structures configured for connection to an isolation transformer assembly;
providing first and second semiconductor die disposed on the first surface of the substrate and connected to the first and second pluralities of conductive traces, respectively; and
providing an encapsulant disposed on the first surface and configured as an encapsulating volume encapsulating the first and second semiconductor die, wherein the encapsulating volume has a height sufficient to allow the plurality of receiving structures to receive the isolation transformer assembly.

22. The method of claim 21, wherein the substrate includes a recess on the first surface, and wherein the first and second semiconductor die are disposed in the recess.

23. The method of claim 21, wherein the plurality of receiving structures comprise pedestals having a height, and wherein the encapsulating volume has a height less than or equal to the height of the pedestals.

24. The method of claim 21, wherein the plurality of receiving structures comprise solder pads.

25. The method of claim 21, wherein the encapsulant comprises molding material.

26. The method of claim 21, wherein the encapsulant comprises a silicone material.

27. The method of claim 21, wherein the isolation transformer assembly comprises a molded package having a plurality of exposed conductive structures corresponding in number to the plurality of receiving structures.

28. The method of claim 21, wherein the first and second pluralities of conductive traces comprise first and second pluralities of solder pads.

29. The method of claim 28, wherein the first and second pluralities of solder pads are disposed on the second surface of the substrate, respectively.

30. The method of claim 29, wherein the first and second pluralities of solder pads comprise land grid array (LGA) pads.

31. The method of claim 28, wherein the first and second pluralities of solder pads are disposed on first and second side surfaces of the substrate, respectively.

32. The method of claim 31, wherein the first and second pluralities of solder pads comprise plated through vias.

33. The method of claim 31, wherein the first and second pluralities of solder pads comprise plated blind vias.

34. The method of claim 21, wherein the first and second pluralities of conductive traces comprise first and second pluralities of solder pads disposed on the second surface of the substrate, respectively.

35. The method of claim 21, further comprising one or more heat-sink structures disposed on the second surface of the substrate.

36. The method of claim 21, wherein the first and second semiconductor die comprise first and second integrated circuits (ICs), respectively.

37. The method of claim 36, wherein the second IC comprises a gate driver.

38. The method of claim 21, wherein the substrate comprises a printed circuit board (PCB).

39. The method of claim 21, further comprising providing an isolation transformer package connected to the plurality of receiving structures, the isolation transformer package including a transformer having first and second transformer coils that are galvanically separated.

40. The method of claim 39, wherein the transformer package further comprises a magnetic core having a soft ferromagnetic material, wherein the first and second transformer coils are configured about the magnetic core and connected to respective pairs of conductive leads.
